(19) United States
(12) Patent Application Publication
(10) Pub. No.: US 2007/0065969 A1
(43) Pub. Date: Mar. 22, 2007

(54) CMOS image sensor and methods of manufacturing the same

(75) Inventors: Yun-Hee Lee, Yongin-si (KR); Byung-Jun Park, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/523,056

(22) Filed: Sep. 19, 2006

(30) Foreign Application Priority Data
Sep. 20, 2005 (KR) 10-2005-0087278

(51) Int. Cl. H01L 21/00

(52) U.S. Cl. 438/57

(57) ABSTRACT

An image sensor and methods of manufacturing the same are provided. An isolation layer of a CMOS image sensor including an active pixel region and a logic circuit region and methods of manufacturing the same are also provided. A method of manufacturing an image sensor having a unit pixel, which includes a photodiode for picking up light and a transistor group for transferring and processing data picked up by the photodiode, is also provided. The methods may include forming a pad oxide layer on a semiconductor substrate. A buffer layer may be formed on an upper surface of the pad oxide layer. An oxidation preventing mask may be formed to expose a device-mounting isolation region. After oxidizing the buffer layer exposed by the oxidation preventing mask, the remaining oxidation preventing mask, buffer layer and pad oxide layer may be removed to form an isolation layer for defining an active region where the photodiode and the transistor group maybe formed.

### PRIORITY STATEMENT

This application claims the benefit of priority under 35 U.S.C. §119 from Korean Patent Application No. 10-2005-0087278, filed on Sep. 20, 2005, in the Korean Intellectual Property Office, the disclosure of which is incorporated herein in its entirety by reference.

### BACKGROUND OF THE INVENTION

1. Field of the Invention

Example embodiments of the present invention relate to an image sensor and methods of manufacturing the same. Other example embodiments of the present invention relate to an isolation layer of a CMOS image sensor including an active pixel region and a logic circuit region and methods of manufacturing the same.

2. Description of the Related Art

Image sensors convert optical signals into electrical signals. Charge coupled devices (CCDs) and CMOS image sensors (CISs) are examples of image sensors. CIS image sensors are widely researched and available. CISs use an image sensing unit (or an active pixel region) and a logic circuit unit for processing signals sensed, or detected, by the image sensing unit, integrated in a single wafer.

A CIS image sensor may include an active pixel region and a logic circuit region. The active pixel region may retrieve an optical image and convert the optical image into an electrical signal. The logic circuit region may convert the electrical signal from the active pixel region into a logic signal and process the logic signal. The active pixel region may have a plurality of unit pixels. The number of unit pixels determines the resolution of the CIS image sensor.

If the number of unit pixels is increased to increase the resolution, then it may be necessary to increase the area occupied by the active pixel region and the semiconductor chip size. When the area occupied by the active pixel region and the semiconductor chip size are increased, the number of image sensors that may be formed in a single wafer may be reduced.

A method of decreasing the area of a unit pixel has been acknowledged by the conventional art. Decreasing the area of a unit pixel may reduce the amount of light incident to the unit pixel, decreasing the fill factor and signal-to-noise (S/N) ratio.

According to conventional methods, in order to provide a larger photodiode area within a unit pixel while decreasing the other parameters (e.g., fill factor and S/N ratio), an isolation layer may be formed in the active pixel region and the logic circuit region by a shallow trench isolation (STI) layer instead of a local oxidation of silicon (LOCOS) layer. Because the STI layer may occupy a smaller area than a LOCOS layer, the STI layer may be used for more highly integrated semiconductor devices. The STI layer may provide a wider active region (e.g., photodiode region) by preventing, or reducing, the occurrence of bird's beak phenomenon, which may be chronic in the LOCOS layer.

Bird's beak phenomenon is a result of two-dimensional oxidation that may occur at an edge of a field oxide during LOCOS oxidation. As such, oxidation extends into an active area at a surface underneath a silicon nitride, forming a bird's beak. Because of the bird's beak, an effective area of the active region may be reduced. In the bird's beak region of a gate oxide, oxide thinning may occur.

The STI layer may be obtained by etching a trench in a semiconductor substrate to a desired depth and filling the trench with oxide. When the semiconductor substrate is etched to form the trench, excessive stress may be applied to the semiconductor substrate. The excessive stress may cause a charge trap in an interfacial surface of the semiconductor substrate. The charge trap increases the dark current irrespective of non-selection of a unit pixel, which may cause characteristics of the CIS image sensor to deteriorate. The excessive stress may occur in the LOCOS layer where the semiconductor substrate is locally oxidized.

Although the STI layer is narrower than the LOCOS layer, the silicon oxide layer of the STI layer may have a larger contact area with the silicon substrate compared to the LOCOS layer. As such, problems with higher dark current may also occur in the STI layer. The dark current may be generated by dangling bonds at interfaces between dissimilar layers (e.g., the silicon substrate and the silicon oxide layer). As the interfacial surface becomes wider, more dangling bonds may occur and the dark current may become greater.

### SUMMARY OF THE INVENTION

Example embodiments of the present invention relate to an image sensor and methods of manufacturing the same. Other example embodiments of the present invention relate to an isolation layer of a CMOS image sensor including an active pixel region and a logic circuit region and methods of manufacturing the same.

Example embodiments of the present invention provide a method of manufacturing an image sensor for preventing stress by preventing, or reducing, direct oxidation of a substrate. Example embodiments of the present invention also provide an image sensor for preventing, or reducing, dark current by avoiding or alleviating stress on a substrate.

According to example embodiments of the present invention, there is provided a method of manufacturing a CMOS image sensor having a unit pixel and a transistor group. The unit pixel may include a photodiode through which light enters. The transistor group transfers and processes data retrieved by the photodiode.

In the method provided, a pad oxide layer may be formed on a semiconductor substrate. A buffer layer may be formed on an upper surface of the pad oxide layer. An oxidation preventing mask may be formed on an upper surface of the buffer layer to expose a device-mounting isolation region. The buffer layer may be oxidized using the oxidation preventing mask. The oxidation preventing mask, the buffer layer and the pad oxide layer remaining on the semiconductor substrate may be removed to form an isolation layer, defining an active region where the photodiode and the transistor group may be formed.

According to other example embodiments of the present invention, there is provided a method of manufacturing a CMOS image sensor having an active pixel region, transistor groups and a logic circuit. The active pixel region may include unit pixels having a photodiode for receiving light. The transistor groups may transfer and process data received by the photodiode. The logic circuit region may be located on the periphery of the active pixel region to convert a signal transferred from the active pixel region to a logic signal.

A semiconductor substrate having the active pixel region and the logic circuit region with the isolation layer is provided as follows. A buffer layer may be formed on an upper surface of the pad oxide layer after forming a pad oxide layer on the semiconductor substrate. An oxidation preventing mask may be formed on an upper surface of the buffer layer to expose a device-mounting isolation region of the active pixel region. The buffer layer exposed by the oxidation preventing mask may be oxidized. An isolation layer may be formed to define the active pixel region (where the photodiode and the transistor groups may be formed) by removing the remaining oxidation preventing mask, buffer layer and pad oxide layer.

The isolation layer in the logic circuit region of the semiconductor substrate may be formed by etching a desired portion of the logic circuit region to form a trench. A surface within the trench may be oxidized to form a sidewall oxide layer. After forming a silicon nitride layer liner along a surface of the sidewall oxide layer, an insulating material may be filled into the trench to form a shallow trench isolation (STI) isolation layer.

According to other example embodiments of the present invention, there is provided a method of manufacturing a CMOS image sensor having an active pixel region and a logic circuit region. The active pixel region may include unit pixels having a photodiode for receiving light and transistor groups for transferring and processing data received by the photodiode. The logic circuit region may be formed, or located, on the periphery of the active pixel region to convert signals transferred from the active pixel region to logic signals. The method may include providing a semiconductor substrate wherein the active pixel region and the logic circuit region are defined. After forming a trench in a desired portion of the logic circuit region, a pad oxide layer may be formed on a surface of the semiconductor substrate and an inner surface of the trench. A buffer layer may be formed on the pad oxide layer, filling the trench. An oxidation preventing mask may be formed on the upper surface of the buffer layer to expose a device-mounting isolation region of the active pixel region and the trench region. The buffer layer, exposed by the oxidation preventing mask, may be oxidized. The remaining oxidation preventing mask, buffer layer and pad oxide layer may be removed to form a LOCOS isolation layer in the active pixel region and a STI layer in the logic circuit region.

In the above example embodiments, the buffer layer may be one selected from the group including a polysilicon layer, an amorphous silicon (a-si) layer, a silicon germanium (SiₓGe_{y}) layer and a germanium (Ge) layer. The buffer layer may be a layer formed by stacking at least one of the polysilicon layer, amorphous silicon layer, silicon germanium layer and/or germanium layer.

According to other example embodiments of the present invention, there is provided a CMOS image sensor having an active pixel region and a logic circuit region. The active pixel region may include unit pixels that each have a photodiode for receiving light and transistor groups for transferring and processing data received by the photodiode. The logic circuit region may be located on the periphery of the active pixel region to convert a signal transferred from the active pixel region to a logic signal. According to example embodiments of the present invention, the active pixel region and the logic circuit region may include an isolation layer for defining an active region. The isolation layer of the active pixel region may be a LOCOS layer protruding, or extending, from the semiconductor substrate by a desired height. The isolation layer of the logic circuit region may be a STI layer buried in the semiconductor substrate.

According to example embodiments of the present invention, the isolation layer of the active pixel region may be formed from a LOCOS oxide layer of the buffer layer. The isolation layer of the logic circuit region may be formed from the STI layer. As such, when forming the isolation layer of the active pixel region, direct oxidation of the substrate may decrease, reducing stress on the semiconductor substrate. Alleviating or reducing stress on the semiconductor substrate may prevent, or reduce, the occurrence of the charge trap phenomenon and/or maintain a lower dark current. Using the buffer layer prevents, or reduces, the bird's beak phenomenon, providing a wider active region compared to the active region formed by the conventional LOCOS. The isolation layer of the logic circuit region may be formed from the STI layer that occupies a relatively smaller area such that the configuration of the active region of the active pixel region may be altered in order to prevent, or circumvent, an increase in the unit pixel area.

### BRIEF DESCRIPTION OF THE DRAWINGS

Example embodiments of the present invention will be more clearly understood from the following detailed description taken in conjunction with the accompanying drawings. FIGS. 1-6 represent non-limiting, example embodiments of the present invention as described herein.

FIGS. 1A through 1D are diagrams illustrating sectional views of a method of manufacturing an active pixel region of a CMOS image sensor according to example embodiments of the present invention;

FIG. 2 is a diagram illustrating a plan view of a pixel structure wherein two photodiodes are connected to a single transistor group according to example embodiments of the present invention;

FIG. 3 is a circuit diagram illustrating the two unit pixels of FIG. 2;

FIG. 4 is a block diagram illustrating a unit chip structure of a CMOS image sensor according to example embodiments of the present invention;

FIGS. 5A through 5D are diagrams illustrating sectional views of a method of manufacturing an active pixel region and a logic circuit region of a CMOS image sensor according to example embodiments of the present invention; and

FIGS. 6A through 6D are diagrams illustrating sectional views of a method of manufacturing an active pixel region and a logic circuit region of a CMOS image sensor according to example embodiments of the present invention.

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments of the present invention.

Spatially relative terms, such as “beneath”, “below”, “lower”, “above”, “upper” and the like, may be used herein for ease of description to describe one element or a feature's relationship to another element or feature as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Also, the use of the words “compound,” “compounds,” or “compound(s),” refer to either a single compound or to a plurality of compounds. These words are used to denote one or more compounds but may also just indicate a single compound.

Example embodiments of the present invention are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments of the invention should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments of the present invention belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to the example embodiments described.

Example embodiments of the present invention relate to an image sensor and methods of manufacturing the same. Other example embodiments of the present invention relate to an isolation layer of a CMOS image sensor including an active pixel region and a logic circuit region and methods of manufacturing the same.

According to example embodiments of the present invention, an isolation layer of an active pixel region is formed from a local oxidation of silicon (LOCOS) oxide layer of a buffer layer, reducing direct oxidation of a substrate. A light-receiving device (e.g., a photodiode) may be located in the active pixel region. Substrate stress may be suppressed to eliminate or reduce charge traps, which increase dark current. In order to compensate for an increase in chip size resulting from using the LOCOS oxide layer of the buffer layer, an isolation layer in a logic circuit region may be formed from a shallow trench isolation (STI) layer.

An example embodiment of manufacturing a LOCOS oxide layer in an active pixel region using a buffer layer will now be described.

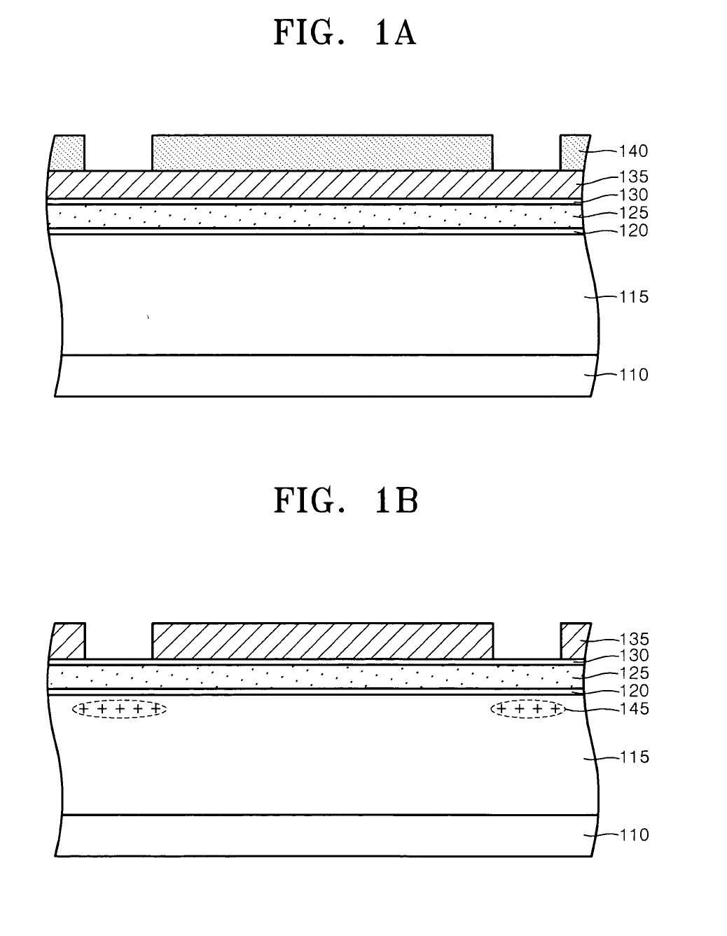

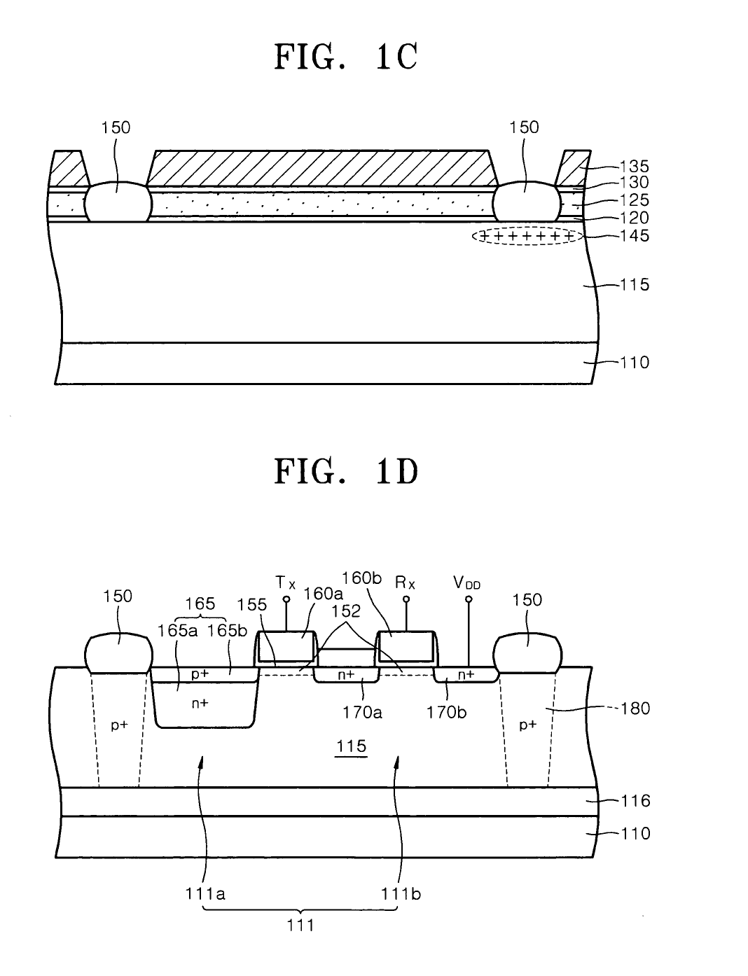

FIGS. 1A through 1D are diagrams illustrating sectional views of a method of manufacturing an active pixel region of a CMOS image sensor according to example embodiments of the present invention.

Referring to FIG. 1A, a semiconductor substrate 110 may include an epitaxial layer 115. The epitaxial layer 115 may deposited or grown on the semiconductor substrate 110. The semiconductor substrate 110 and the epitaxial layer 115 may form a p-type or an n-type silicon substrate. The epitaxial layer 115 may be an impurity layer. The impurity layer may be p-type or n-type. For example, the epitaxial layer 115 may be a p-type impurity layer obtained by epitaxially growing the epitaxial layer on the semiconductor substrate 110.

A pad oxide layer 120 and a buffer layer 125 may be formed on the upper surface of the epitaxial layer 115. The pad oxide layer 120 may be formed by wet oxidizing or dry oxidizing the surface of the epitaxial layer 115 to a thickness of 50 Å-250 Å.

During local oxidation for device isolation (performed later), the buffer layer 125 may be oxidized instead of the semiconductor substrate. The buffer layer may include at least one layer selected from the group including a polysilicon layer, an amorphous silicon (a-si) layer, a silicon germanium (SixGey) layer and a germanium (Ge) layer. The buffer layer 125 may be formed having a thickness of 500 Å-2000 Å by low pressure chemical vapor deposition (LPCVD) at a temperature of 500° C.-700° C.

A silicon nitride layer 135, which is an oxidation stop layer, may be formed on the upper surface of the buffer layer 125. The silicon nitride layer 135 may be formed having a thickness of 2000Å-3000 Å, using LPCVD. If the silicon nitride layer 135 has a thickness of 2000 Å-3000 Å, then a silicon oxide layer 130 may be formed between the buffer layer 125 and the silicon nitride layer 135 as an interface buffering layer to increase bonding between the buffer layer 125 and the silicon nitride layer 135. A photoresist pattern 140 for defining an active region may be formed on the upper surface of the silicon nitride layer 135 by photolithography.

Referring to FIG. 1B, the silicon nitride layer 135 may be etched in the form of the photoresist pattern 140. The photoresist pattern 140 may be removed. Using the silicon nitride layer 135 as a mask, field stop ions 145 may be implanted into a device-mounting isolation region. The field stop ions 145 may have the same impurity type as the epitaxial layer 115. The field stop ions 145 may remove a charge trap of an interfacial surface of the isolation layer and the semiconductor substrate 110.

Referring to FIG. 1C, using the patterned silicon nitride layer 135 as a mask, the exposed silicon oxide layer 130 and the underlying buffer layer 125 may be locally oxidized to form an isolation layer 150. Oxidation of the buffer layer 125 may be performed in a furnace under an O₂ or H₂O gaseous atmosphere.

When oxidizing to form the isolation layer 150, the semiconductor substrate 110 and/or the epitaxial layer 115 under the buffer layer 125 may be partially oxidized. Partial oxidation of the semiconductor substrate according to example embodiments of the present invention may be less than the substrate oxidation performed according to the conventional LOCOS layer. Partial oxidation of the semiconductor substrate may apply negligible stress to the substrate. Because the buffer layer 125 is oxidized, the occurrence of bird's beak phenomenon is prevented, or reduced.

Referring to FIG. 1D, the remaining silicon nitride layer 135, silicon oxide layer 130, buffer layer 125 and pad oxide layer 120 may be removed. The isolation layer 150 may be formed in a unit pixel region. According to example embodiments of the present invention, the silicon nitride layer 135 may be removed by a PH₃ solution. The silicon oxide layer 130 and the pad oxide layer 120 may be removed by HF or a buffered oxide etchant (BOE) solution. The buffer layer 125 may be removed by a silicon removing solution (e.g., low ammonium liquid (LAL)). By removing the buffer layer 125, the isolation layer 150 in the form of a LOCOS oxide layer (which defines an active region 111) may be formed on the semiconductor substrate 110.

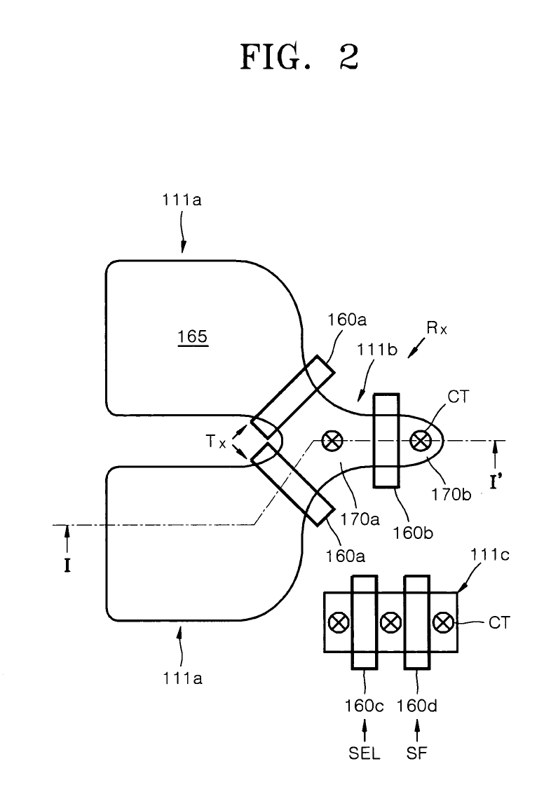

Referring to FIG. 2, the active region 111 defined by the isolation layer 150 includes a first active region 111a, second active region 111b and third active region 111c. A photodiode (or a light receiving unit) may be formed in the first active region 111a. The transistors, which process signals received by the photodiodes, may be formed in the second active region 111b and the third active region 111c. FIG. 2 is a diagram illustrating a plan view of a pixel structure wherein two photodiodes are connected to a transistor group according to example embodiments of the present invention.

As shown in FIG. 2, two unit pixels are provided wherein the isolation layer 150 may be formed to allow two first active regions 111a to share the second region 111b and third active region 111c. Although the third active region 111c is shown spaced apart from the first active region 111a and second active region 111b, the third active region 111a may be electrically connected to a transistor formed on the second active region 111b using a metal interconnect, later in the process. The active region 111 may be formed such that a single first active region 111a may be connected to a single second active region 111b.

A gate oxide layer 155 and a conductive layer for a gate electrode may be deposited on the upper surface of the semiconductor substrate 110 where the isolation layer 150 is formed. By patterning the conductive layer for the gate electrode, a transfer gate 160a and a reset gate 160b may be formed on desired portions of the second active region 111b. As shown in FIG. 2, a select gate 160c and a source follower gate 160d may be simultaneously formed on the third active region 111c when the gates 160a and 160b are formed.

Between forming the isolation layer 150 and forming the gate oxide layer 155, a deep p-well 116 may be added within the semiconductor substrate 110 or the epitaxial layer 115, as necessary. Before forming the gates 160a and 160b, an impurity may be selectively ion implanted in a gate electrode-mounting region to form a threshold-voltage (V_{T}) for adjusting an ion region 152, eliminating dangling bonds present in a hetero-junction surface (e.g., silicon-silicon oxide layer). The impurity may be (e.g., a p-type) identical to the impurity of the epitaxial layer 115.

An n-type photodiode region 165a may be formed in the first active region 111a on a side of the transfer gate 160a. A p-type photodiode region 165b may be formed on the upper surface of the n-type photodiode region 165a, forming a photodiode 165. The n-type photodiode region 165a and the p-type photodiode region 165b may be obtained by tilt ion implanting an impurity.

An impurity (e.g., an n-type) may be ion implanted into the other side of the transfer gate 160a and both sides of the reset gate 160b to form a floating diffusion region 170a and a junction region 170b, forming the transistors.

Reference numeral 180 in FIG. 1D denotes a device isolation impurity region. The device isolation impurity region 180 may be formed between the isolation layer 150 and the deep well 116 to insulate the unit pixels from each other. The device isolation impurity region 180 may function as a conduit for supplying power to the semiconductor substrate 110. In FIG. 2, CT denotes a contact of the floating diffusion region 170a and the junction region 170b.

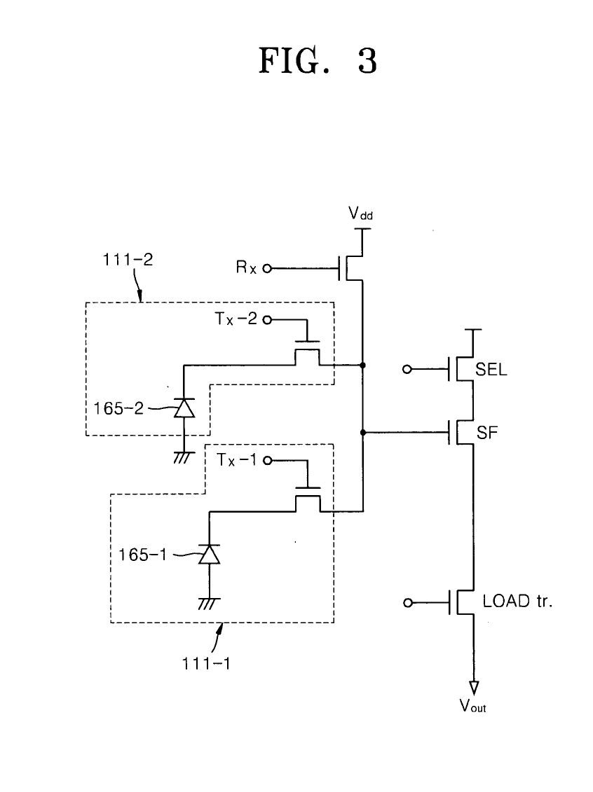

FIG. 3 is a circuit diagram illustrating two unit pixels that share a single transistor group (as shown in FIG. 2). Referring to FIG. 3, a first photodiode 165-1 and a first transfer transistor Tx-1 of a first unit pixel 111-1 may be connected in parallel with a second photodiode 165-2 and a second transfer transistor Tx-2 of a second unit pixel 111-2. Drains (e.g., floating diffusion region) of the first transfer transistor Tx-1 and second transfer transistor Tx-2 of two unit pixels may be connected to a reset transistor Rx supplied with a reset signal. Drains of the first transfer transistor Tx-1 and second transfer transistor Tx-2 of two unit pixels may be connected in series with a source follower transistor SF and a transistor SEL that selects the two unit pixels. An output node of the source follower transistor SF may be connected to a load transistor LOAD tr.

According to example embodiments of the present invention, an isolation layer of a unit pixel may be formed from a LOCOS oxide layer of a buffer layer. The buffer layer may be used as an oxidation medium when performing a LOCOS process, reducing substrate stress. The lower substrate stress may reduce charge traps and/or dark current.

According to example embodiments of the present invention, two photodiodes may be connected to a single transistor group such that a unit pixel area may decrease even if the fill factor and/or S/N ratio do not decrease.

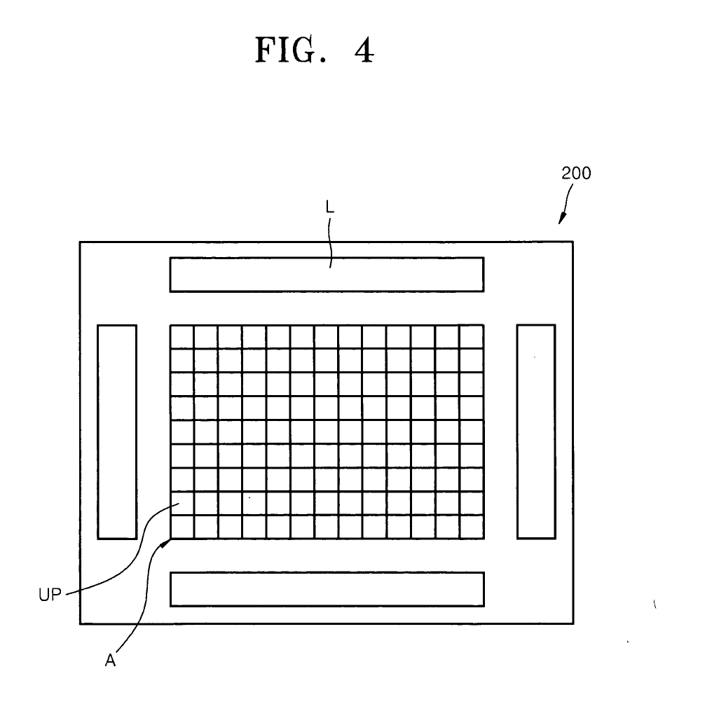

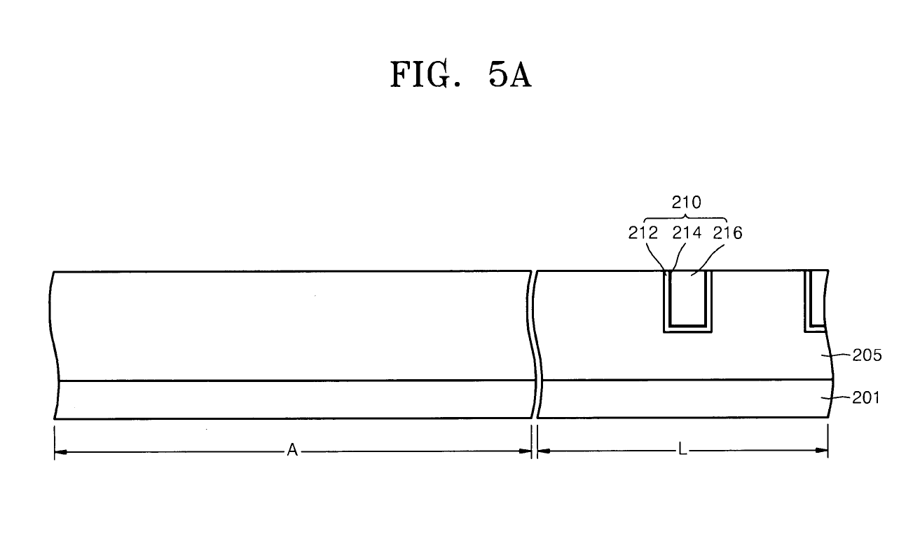

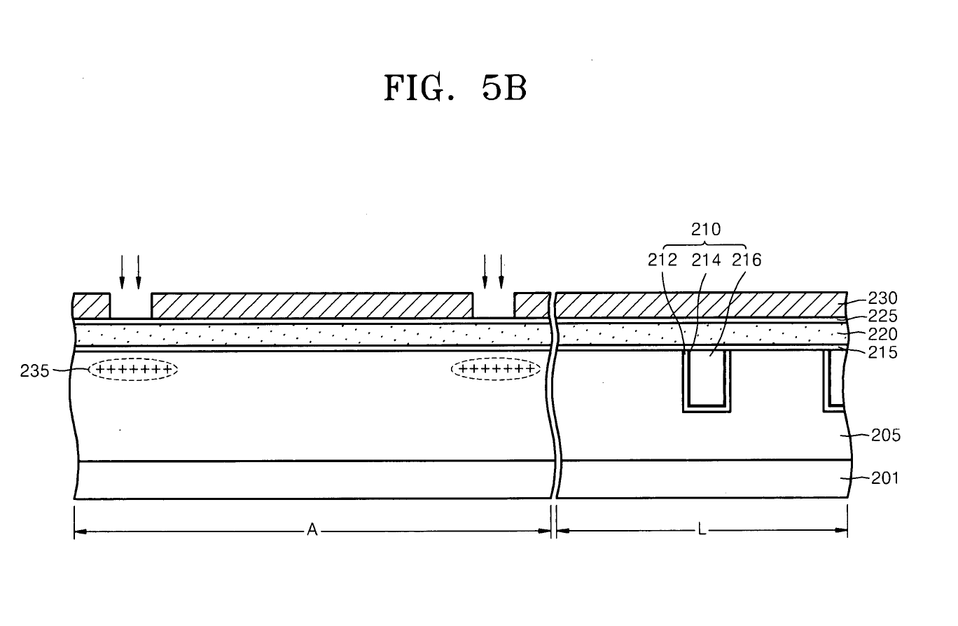

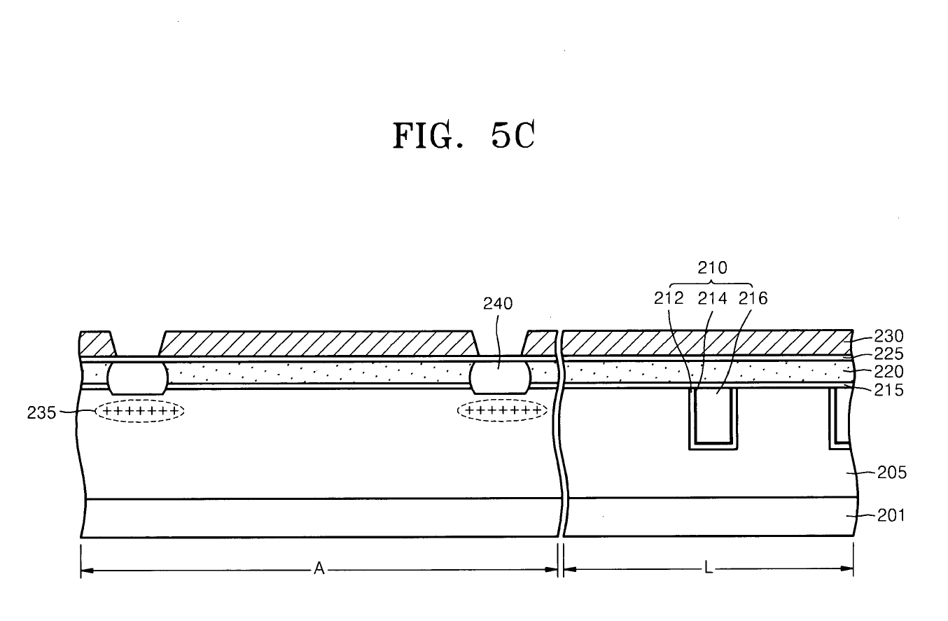

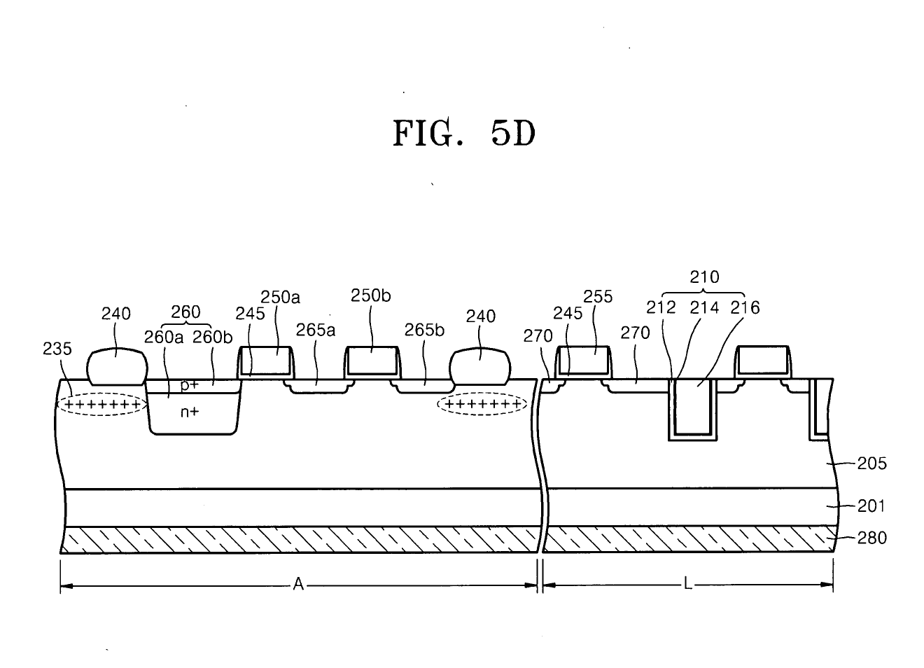

FIG. 4 is a block diagram illustrating a unit chip structure of a CMOS image sensor according to example embodiments of the present invention. FIGS. 5A through 5D are diagrams illustrating sectional views of a method of manufacturing an active pixel region and a logic circuit region of an CMOS image sensor according to example embodiments of the present invention.

Referring to FIG. 4, an active pixel region A may be located on a chip 200 of an image sensor. A logic circuit region L that converts a signal generated by the active pixel region A into a logic signal and processes the logic signal may be located on the periphery of the active pixel region A.

The active pixel region A may include a plurality of unit pixels (UP). Each UP may include a photodiode, a transfer transistor, a reset transistor, a select transistor and/or a source follower. The photodiode may convert light into an electrical signal. Collectively, the transfer transistors, the reset transistor, the select transistor and the source follower may transfer and amplify the signal generated by the photodiode, as shown in FIGS. 2 and 3.

A method of forming isolation layers in the active pixel region A and a logic circuit region L will now be described.

Referring to FIG. 5A, an epitaxial layer 205 may be formed on a semiconductor substrate 201. As described above, the semiconductor substrate 201 may be a p-type or an n-type silicon substrate. The epitaxial layer 205, which may be a p-type impurity layer, may be formed by epitaxially growing the semiconductor substrate 201. A portion of the logic circuit region L may be etched to form a trench. An inner wall of the trench may be oxidized to repair defects and/or damage to a silicon lattice resulting from the trench formation. A sidewall oxide layer 212 may be formed along the inner wall of the trench from the oxidation of the inner wall. Because the logic circuit region L does not receive light, problems (e.g., high dark current) are likely not to occur even if stress is applied to the substrate (which causes a charge trap). A silicon nitride layer liner 214 may be formed on the surface of the sidewall oxide layer 212 to relieve stress caused by the different thermal expansion coefficient of an insulating material that may fill the trench. An insulating layer 216 may be formed on the silicon nitride layer liner 214 to fill the trench, forming a shallow trench isolation (STI) layer 210 in the logic circuit region L. The insulating layer 216 may be formed of high density plasma (HDP) oxide, plasma enhanced-tetraethylorthosilicate (PE-TEOS), middle temperature oxide (MTO) (e.g., USG oxide) or a combination of thereof.

Referring to FIG. 5B, a pad oxide layer 215, a buffer layer 220, an interfacial buffer layer 225 and/or a silicon nitride layer 230 may be sequentially stacked on the upper surface of the semiconductor substrate 201 where the STI layer 210 is formed in the logic circuit region L. The buffer layer 220 may be oxidized in place of the semiconductor substrate 201 when a LOCOS process is performed to form the isolation layer of the pixel region, as described in the foregoing example embodiments. The buffer layer 220 may be formed of at least one layer selected from the group including a polysilicon layer, an amorphous silicon (a-si) layer, a silicon germanium (SiₓGe_{y}) layer and a germanium (Ge) layer. The buffer layer 125 may be formed having a thickness of 500 Å-2000 Å by LPCVD at a temperature of 500° C.-700° C. The interfacial buffer layer 225 may be formed of silicon oxide as described above.

The silicon nitride layer 230 may be etched to expose a pre-isolation region of the active pixel region. The silicon nitride layer 230 may also be formed on the logic circuit region L. Field stop ions 235 may be implanted into the exposed device-mounting isolation region.

Referring to FIG. 5C, the buffer layer 220 of the exposed device-mounting isolation region may be oxidized to form a LOCOS isolation layer 240. The oxidation of the buffer layer 220 may be performed by dry oxidation using O₂ gas, or wet oxidation using an H₂O supply, in a furnace.

Referring to FIG. 5D, the remaining silicon nitride layer 230, the silicon oxide layer 225, the buffer layer 220 and the pad oxide layer 215 may be removed, forming the isolation layer 240 in the form of the LOCOS layer in the active pixel region A and the STI layer 210 in the logic circuit region L.

As described in the above example embodiments, a photodiode 260, a transfer gate 250a, a reset gate 250b, a floating diffusion region 265a and a junction region 265b may be formed in the active pixel region A. When forming the transfer gate 250a and the reset gate 250b of the active pixel region A, a logic gate 255 may be simultaneously formed in the logic circuit region L. When forming the junction region 265b of the active pixel region A, a junction region 270 may be simultaneously formed in the logic circuit region L. A conductive layer 280 may be formed on a back side of the semiconductor substrate 201 to supply external electrical power to the semiconductor substrate 201. If not a conductive layer 280 is not formed on the back side of the semiconductor substrate 201, an impurity region may be formed under a lower portion of the isolation layer 240 as shown in FIG. 1D to form a path that supplies an external electrical power to the semiconductor substrate 201.

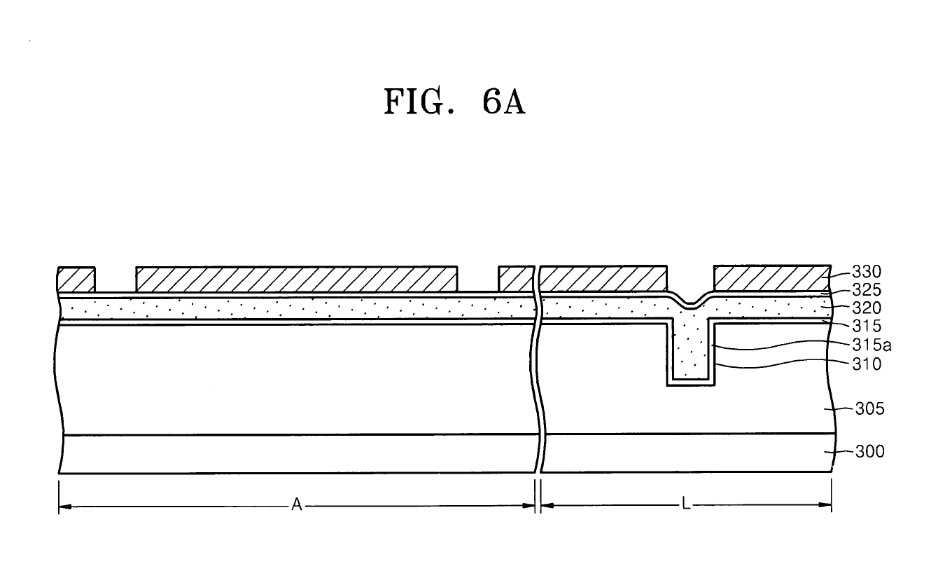

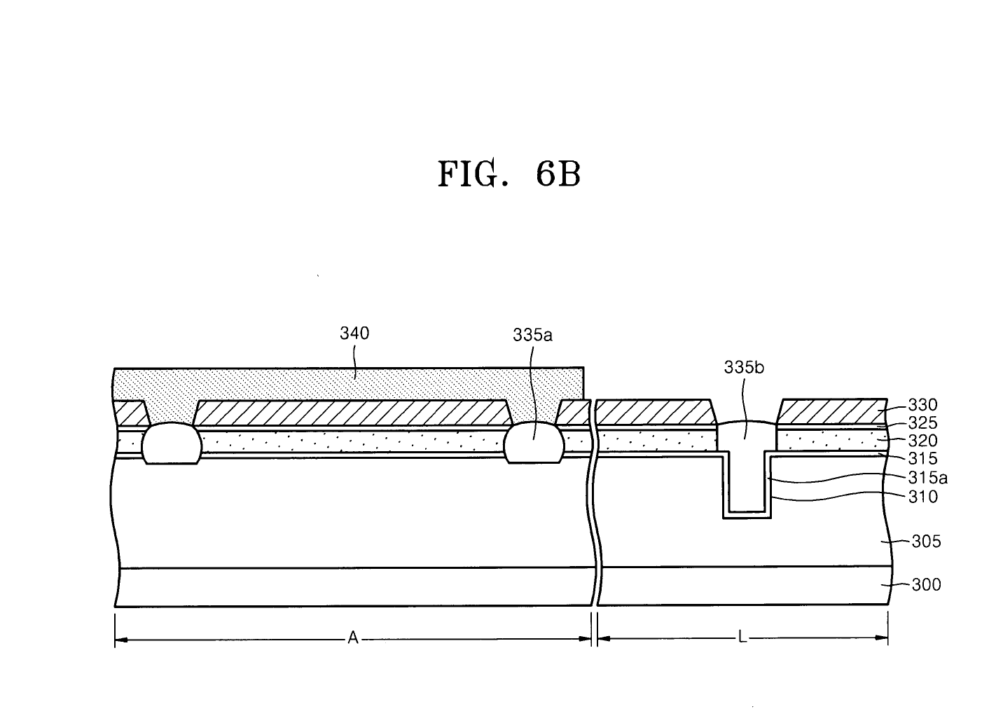

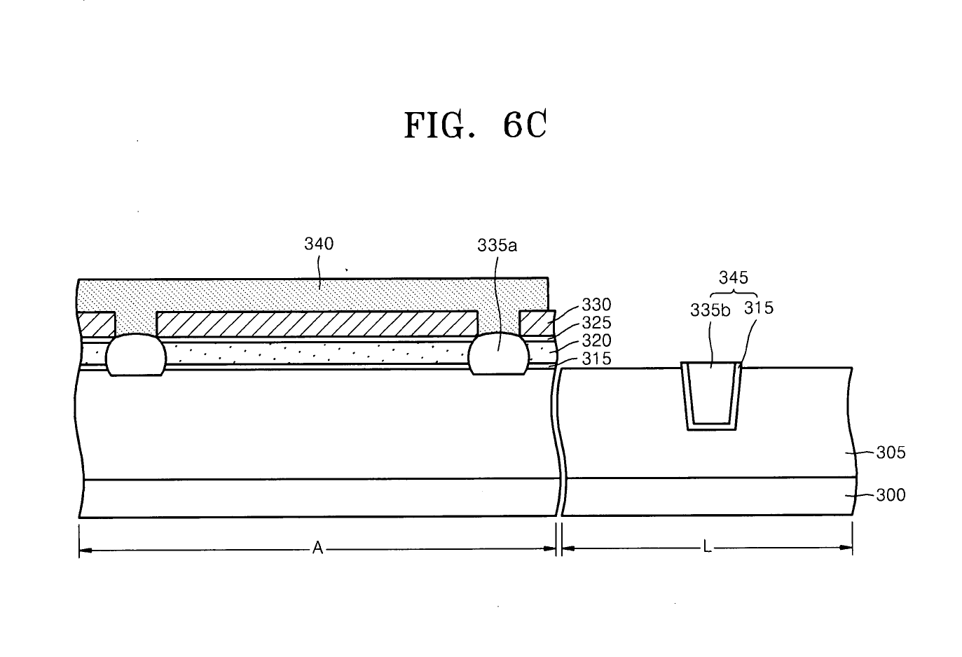

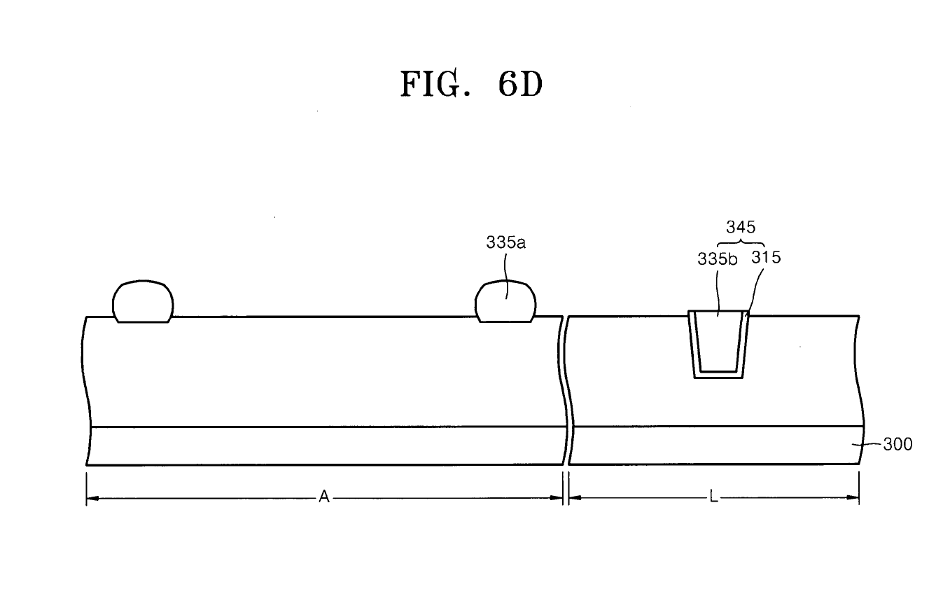

The isolation layer 240 of the active pixel region and the isolation layer 240 of the logic circuit region may be simultaneously manufactured as shown in FIGS. 6A through 6D.

As shown in FIG. 6A, a portion of a logic circuit region L of a semiconductor substrate 300, which has an epitaxial layer 305 formed thereon may be etched to form a trench 310. As described above, because the logic circuit region L does not receive light, the logic circuit L may not be affected by charge traps caused by substrate stress. The logic circuit L may not affect the dark current. As such, the surface of the epitaxial layer 305 may be oxidized to form a pad oxide layer 315 on an active pixel region A. Simultaneously, a sidewall oxide layer 315a may be formed along an inner surface of the trench 310.

A buffer layer 320 may be deposited to fill the trench 310. As described in the foregoing example embodiments, the buffer layer 320 may be formed of at least one layer selected from the group including a polysilicon layer, an amorphous silicon (a-si) layer, a silicon germanium layer (SiₓGe_{y}) and a germanium (Ge) layer.

A silicon nitride layer liner may be selectively formed along an inner wall of the trench 310 (as shown in FIG. 5A) prior to depositing the buffer layer 320. The selective forming of the silicon nitride layer liner within the trench 310 may be performed by depositing a silicon nitride layer on the surface of the pad oxide layer 315 and anisotropically etching the silicon nitride layer, leaving the silicon nitride layer liner within the trench 310. After forming a silicon oxide layer 325 as an interfacial buffer layer on the upper surface of the buffer layer 320, a silicon nitride layer 330 may be formed. The silicon nitride layer 330 may be patterned to expose device-mounting isolation regions of the active pixel region A and the logic circuit region L. The patterned silicon nitride layer 330 may expose the trench 310 portion of the logic circuit region L. The patterned silicon nitride layer 330 may also expose a peripheral portion of the trench 330.

Referring to FIG. 6B, using the patterned silicon nitride layer 330 as a mask, the exposed buffer layer 320 may be oxidized to form a LOCOS oxide layer 335a and an oxide layer 335b for filling. The trench 310 portion of the logic circuit region L. Oxidation may be performed until the buffer layer 320 within the trench 310 is completely oxidized. In order to increase the oxidation efficiency, the buffer layer 320 may be oxidized while supplying a plasma. A shielding layer 340 (e.g. a photoresist layer) may be formed to shield the active pixel region A.

When the shielding layer 340 covers the active pixel region A (as shown in FIG. 6C) the silicon nitride layer 330, the silicon oxide layer 325, the buffer layer 320 and the pad oxide layer 315 remaining on the logic circuit region L may be removed, planarizing the oxide layer 335b that fills the trench 310 portion of the logic circuit region L. An etch-back or chemical mechanical polishing (CMP) process may be performed to planarize the oxide layer 335b.

Referring to FIG. 6D, the shielding layer 340, the silicon nitride layer 330, the silicon oxide layer 325, the buffer layer 320 and the pad oxide layer 315 remaining on the active pixel region A may be removed by any removal method known in the art, leaving only the LOCOS oxide layer 335a on the active pixel region A. Although not illustrated, the photodiode and transistors may be formed in the active pixel region A. The transistors may be formed in the logic circuit region L, as shown in FIG. 5D.

According to example embodiments of the present invention, a LOCOS oxide layer using a buffer layer may be formed having an isolation layer to separate elements in an active pixel region (e.g., a unit pixel region). The buffer layer may be oxidized, instead of the substrate, to form the LOCOS oxide layer. As such, substrate stress may be reduced and/or the occurrence of charge traps may be decreased. As the occurrence of charge traps decreases, the dark current may also decrease.

Two photodiodes connected to a single transistor group in the example embodiments set forth herein (which are not limited thereto) may be applied to various kinds of CMOS image sensors.

The foregoing is illustrative of the example embodiments of the present invention and is not to be construed as limiting thereof Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of manufacturing a CMOS image sensor, comprising:
forming a pad oxide layer on a semiconductor substrate;
forming a buffer layer on an upper surface of the pad oxide layer;
forming an oxidation preventing mask on an upper surface of the buffer layer to expose a device-mounting isolation region;
oxidizing the buffer layer; and
removing the oxidation preventing mask, the buffer layer and the pad oxide layer remaining on the semiconductor substrate to form an isolation layer that defines an active region where a photodiode and a transistor group will be formed,
wherein the CMOS image sensor has a unit pixel that includes the photodiode for receiving light and a transistor group for transferring and processing data received by the photodiode.

2. The method of claim 1, wherein the buffer layer is a layer selected the group including a polysilicon layer, an amorphous silicon (a-si) layer, a silicon germanium (SiₓGe_{y}) layer and a germanium (Ge) layer.

3. The method of claim 1, wherein the buffer layer is formed by stacking at least one layer selected from the group including a polysilicon layer, an amorphous silicon (a-si) layer, a silicon germanium (SiₓGe_{y}) layer and a germanium (Ge) layer.

4. The method of claim 2, further comprising forming a silicon oxide layer on an upper surface of the buffer layer, after forming the buffer layer and prior to forming the oxidation preventing mask.

5. The method of claim 4, wherein the forming of the oxidation preventing mask includes forming a silicon nitride layer on an upper surface of the silicon oxide layer; and patterning the silicon nitride layer to expose the device-mounting isolation region.

6. The method of claim 1, further comprising implanting an impurity, which is a same type as that of the semiconductor substrate, into the semiconductor substrate, after forming the oxidation preventing mask and prior to oxidizing the buffer layer.

7. The method of claim 1, further comprising forming an epitaxial layer on the semiconductor substrate, prior to forming the pad oxide layer.

8. The method of claim 1, further comprising:
forming a transfer gate, a reset gate, a select gate and a source follower gate on the active region each including a gate oxide layer, after forming the isolation layer;
forming the photodiode in the active region on a side of the transfer gate; and
forming a junction region by implanting an impurity into another side of the transfer gate and both sides of the reset gate, the select gate and the source follower gate.

9. The method of claim 1, wherein oxidizing the buffer layer includes wet etching or dry etching.

10. The method of claim 1, further comprising:
providing the semiconductor substrate where the active pixel region and a logic circuit region are defined, prior to forming the pad oxide layer,
wherein the logic circuit region includes the isolation layer and is located on a periphery of the active pixel region to convert a signal transferred from the active region to a logic signal and the active pixel region includes a plurality of unit pixels and the device-mounting isolation region,
further wherein oxidizing the buffer layer is performed on a portion of the buffer layer exposed by the oxidation preventing mask.

11. The method of claim 10, wherein the providing of the semiconductor substrate includes:
etching a desired portion of the logic circuit region of the semiconductor substrate to form a trench;
oxidizing a surface of the trench to form a sidewall oxide layer;
forming a silicon nitride layer liner along a surface of the sidewall oxide layer; and
filling the trench with an insulating material to form a shallow trench isolation (STI) isolation layer.

12. The method of claim 11, further comprising forming a silicon oxide layer on an upper surface of the buffer layer, prior to forming the buffer layer and before forming the oxidation preventing mask.

13. The method of claim 10, wherein the buffer layer is a layer selected from the group including a polysilicon layer, an amorphous silicon (a-si) layer, a silicon germanium (SiₓGe_{y}) layer and a germanium (Ge) layer.

14. The method of claim 10, wherein the buffer layer is formed by stacking at least one layer selected from the group including a polysilicon layer, an amorphous silicon (a-si) layer, a silicon germanium (SiₓGe_{y}) layer and a germanium (Ge) layer.

15. The method of claim 10, wherein the forming of the oxidation preventing mask includes:
forming a silicon nitride layer on an upper surface of the buffer layer; and
patterning the silicon nitride layer to expose the device-mounting isolation region of the active pixel region.

16. The method of claim 10, further comprising implanting an impurity, which is a same type as that of the semiconductor substrate, into the semiconductor substrate, prior to forming the oxidation preventing mask and after oxidizing the buffer layer.

17. The method of claim 10, wherein oxidizing the buffer layer includes wet etching or dry etching.

18. The method of claim 10, further comprising:
forming gates including gate oxide layers on desired locations of the active pixel region and the logic circuit region, after forming the isolation layer in the active pixel region;
forming the photodiode in a desired portion of the active pixel region; and
selectively forming junction regions in the active pixel region in both sides of the gate.

19. The method of claim 18, further comprising forming an impurity region under a lower portion of the isolation layer of the active pixel region, wherein the impurity region is electrically connected to an epitaxial layer.

20. The method of claim 10, further comprising forming an epitaxial layer on the semiconductor substrate, prior to forming the pad oxide layer.

21. The method of claim 10, further comprising forming a conductive layer on a rear surface of the semiconductor substrate to supply an electrical power source voltage or a ground voltage to the semiconductor substrate.

22. The method of claim 1, further comprising:
providing the semiconductor substrate where an active pixel region and a logic circuit region are defined, wherein the logic circuit region is located on a periphery of the active pixel region to convert a signal transferred from the active region to a logic signal, the active pixel region includes a plurality of unit pixels; and
forming a trench in a desired portion of the logic circuit region, prior to forming the pad oxide layer;
wherein the pad oxide layer is formed on a surface the semiconductor substrate and an inner surface of the trench, forming the buffer layer includes filling the trench, forming the oxidation preventing mask exposes the device-mounting isolation region of the active pixel region and a trench region, and oxidizing the buffer layer is performed on a portion of the buffer layer exposed by the oxidation preventing mask,
further wherein removing the oxidation preventing mask, the buffer layer, and the pad oxide layer remaining on the semiconductor substrate forms a local oxidation of silicon (LOCOS) layer in the active pixel region and a shallow trench isolation (STI) layer in the logic circuit region.

23. The method of claim 22, wherein the buffer layer is a layer selected from the group including a polysilicon layer, an amorphous silicon (a-si) layer, a silicon germanium (SiₓGe_{y}) layer and a germanium (Ge) layer.

24. The method of claim 22, wherein the buffer layer is formed by stacking at least one layer selected from the group including a polysilicon layer, an amorphous silicon (a-si) layer, a silicon germanium (SiₓGe_{y}) layer and a germanium (Ge) layer.

25. The method of claim 22, further comprising forming a silicon oxide layer on an upper surface of the buffer layer, prior to forming the buffer layer and after forming the oxidation preventing mask.

26. The method of claim 22, wherein the forming of the oxidation preventing mask includes:
forming a silicon nitride layer on an upper surface of the silicon oxide layer; and
patterning the silicon nitride layer to expose the device-mounting isolation region of the active pixel region and the trench portion of the logic circuit region.

27. The method of claim 22, further comprising implanting an impurity, which is a same type as that of the semiconductor substrate, into the semiconductor substrate, prior to forming of the oxidation preventing mask and after oxidizing the buffer layer.

28. The method of claim 22, wherein the oxidizing of the buffer layer is performed until the buffer layer within the trench is oxidized.

29. The method of claim 28, wherein oxidizing the buffer layer is performed in an oxygen plasma ambient.

30. The method of claim 22, wherein the removing of the oxide preventing mask, the buffer layer, and the pad oxide layer remaining on the substrate includes:
forming a shielding layer on the active pixel region;
removing the oxidation preventing mask, the buffer layer, the pad oxide layer, and a portion of the oxidized buffer layer of the logic circuit region exposed by the shielding layer to planarize the surface of the semiconductor substrate;
removing the shielding layer; and
removing the oxidation preventing mask, the buffer layer and the pad oxide layer remaining on the active pixel region.

31. The method of claim 30, wherein the shielding layer is a photoresist layer.

32. The method of claim 31, wherein the oxidation preventing mask, the buffer layer, the pad oxide layer, and the oxidized buffer layer of the logic circuit region are planarized by etch back or chemical mechanical polishing.

33. A CMOS image sensor, comprising:
an active pixel region including unit pixels that each have a photodiode for picking up light and transistor groups for transferring and processing data picked up by the photodiode; and
a logic circuit region located on a periphery of the active pixel region to convert a signal transferred from the active pixel region to a logic signal,
wherein the active pixel region and the logic circuit region include the isolation layer for defining an active region,
further wherein the isolation layer of the active pixel region is a LOCOS layer protruding from the semiconductor substrate by a desired height and the isolation layer of the logic circuit region is an STI layer within the semiconductor substrate.
